(19) United States
(12) Patent Application Publication
(10) Pub. No.: US 2025/0355152 A1
(43) Pub. Date: Nov. 20, 2025

(54) INTERFEROMETRIC FILTERS FOR PCAMBER CONVERTERS

(71) Applicant: Lumileds LLC, San Jose, CA (US)

(72) Inventors: Antonio LOPEZ-JULIA, Vaals (NL); Thomas DIEDERICH, Stolberg (DE); Rémi GUILLEBOT, Vaals (NL)

(73) Assignee: Lumileds LLC, San Jose, CA (US)

(21) Appl. No.: 18/664,634

(22) Filed: May 15, 2024

(51) Int. Cl. G02B 5/28; F21S 41/141; G02B 1/11; H01L 33/50

(52) U.S. Cl. CPC G02B 5/285; H10H 20/8515; F21S 41/141; G02B 1/11

(57) ABSTRACT

A device is provided. The device includes a converter layer and a filter. The converter layer includes a light emitting surface and an opposite side of the light emitting surface. The filter is deposited on the opposite side. The filter influences a radiation profile to increase a coupling efficiency of a pump radiation into the converter layer.

### BACKGROUND

Conventional automotive technologies include ceramic phosphor converted-amber (pc-amber) light emitting diodes (LEDs), which use high performance ceramic phosphors. Further, because optimized films do not allow for full conversion of pump radiation of the pc-amber LEDs, existing designs for the pc-amber LEDs use interferometric filters at a light emitting surface (LES) to reflect back the pump radiation (e.g., the interferometric filters are an optical filter that reflect the pump radiation back). Yet, conventional automotive technologies have a limited coupling efficiency of pump radiation into a converter layer of the pc-amber LEDs. A solution is needed.

### SUMMARY

According to one or more embodiments, a device is provided. The device includes a converter layer and a filter. The converter layer includes a light emitting surface and an opposite side of the light emitting surface. The filter is deposited on the opposite side. The filter influences a radiation profile to increase a coupling efficiency of a pump radiation into the converter layer.

According to one or more embodiments, an apparatus is provided. The apparatus includes a light emitting diode emitting light and a converter layer. The convert layer includes a light emitting surface and an opposite side of the light emitting surface. The apparatus includes a filter deposited on the opposite side and between the converter layer and the light emitting diode. The filter influences a radiation profile of the light from the light emitting diode. The apparatus includes a second filter deposited on the light emitting surface. The second filter reflects into the converter one or more portions of light exiting the light emitting surface.

### BRIEF DESCRIPTION OF THE DRAWINGS

A more detailed understanding can be had from the following description, given by way of example in conjunction with the accompanying drawings wherein:

FIG. 1 shows a cross section of a device according to one or more embodiments;

FIG. 2 shows a cross section of a device according to one or more embodiments;

FIG. 3 shows a cross section of a device according to one or more embodiments;

FIG. 4 depicts a graph according to one or more embodiments;

FIG. 5 depicts a graph according to one or more embodiments;

FIG. 6 depicts a graph according to one or more embodiments;

FIG. 7 depicts a graph according to one or more embodiments;

FIG. 8 depicts a table according to one or more embodiments;

FIG. 9 depicts a table according to one or more embodiments;

FIG. 10 depicts a table according to one or more embodiments;

FIG. 11 is a diagram of an example vehicle headlamp system; and

FIG. 12 is a diagram of another example vehicle headlamp system.

### DETAILED DESCRIPTION

Conventional automotive technologies, such as the pc-amber light emitting diodes (LEDs) described above, have a limited coupling efficiency of pump radiation into a converter layer. In embodiments described herein, a second interferometric layer stack may be provided on the side of such pc-amber LEDs opposite the light-emitting surface (LES) to increase the coupling efficiency of the pump radiation into the converter layer.

More specifically, embodiments described herein provide for a LED assembly. Examples of the LED assembly include, but are not limited to, a pc-amber LED assembly, which can include at least a converter layer, a filter, and an LED die. The converter layer may include a light emitting surface and a surface opposite the light emitting surface. The filter can be deposited on the surface opposite the light emitting surface. When the filter is placed adjacent the surface opposite the light emitting surface, the filter may be configured to influence a radiation profile of the LED assembly to increase the coupling efficiency of the pump radiation from the LED die into the converter layer.

In some embodiments, the LED assembly can include an anti-reflective coating deposited on the light emitting surface. According to one or more embodiments, the device can include another filter deposited on the light emitting surface. The filter and the other filter can be interferometric photonic bandgap filters and/or dichroic filters. Inclusion of the other filter and the anti-reflective coating can result in an improved conversion efficiency (CE) of pc-amber based emitters by radiation profile influence and by color control, flux control, transmission characteristics control, and radiation characteristics control, as well as providing control of a uniform emission profile and shade intensity. Note that CE considers an ability of the converter layer to convert pump radiation into the phosphor emission while excluding the in-coupling efficiency of pump radiation into the converter layer. Further, CE is a ratio between a he total output power (in photometric units: lumens or lm) and an in-coupled pump radiation power (radiometric units, Watts or W opt).

Examples of different light illumination systems and/or LED implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

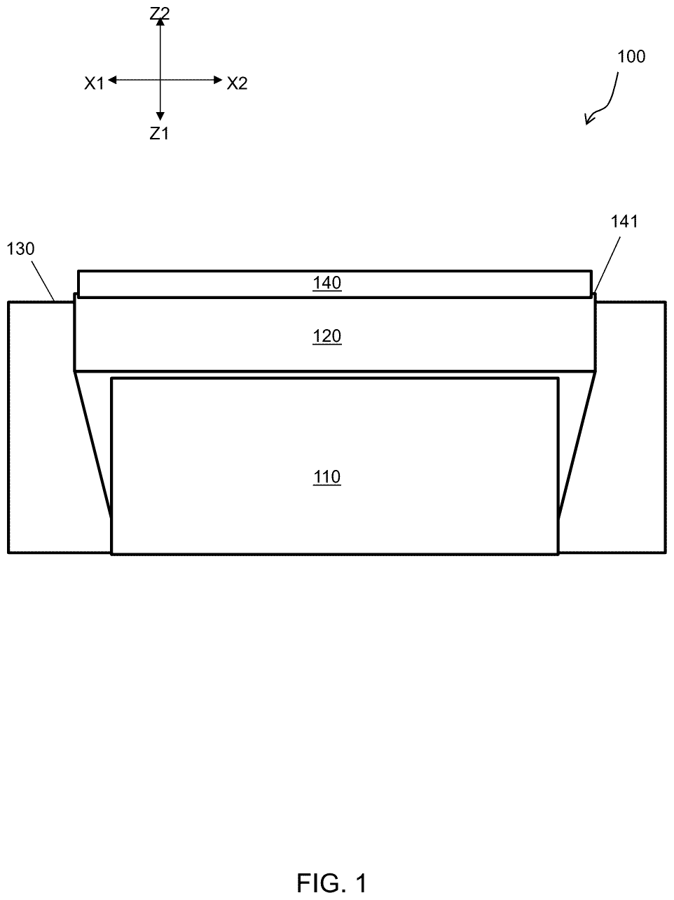

FIG. 1 shows a cross section of a device 100 according to one or more embodiments.

The device 100 of FIG. 1 is shown as a cross section oriented according to an X1-X2 axis and a Z1-Z2 axis. The X1-X2 axis is generally horizontal as oriented in the Figures, with the X1-X2 axis having a direction between left (X1) and right (X2). Accordingly, the X1 direction is opposite the X2 direction, reference to a left side or left facing surface of a component may be referred to as an X1 side or an X1 surface of the component, and reference to a right side or right facing surface of a component may be referred to as an X2 side or an X2 surface of the component. The Z1-Z2 axis is generally vertically as oriented in the Figures, with the axis having a direction between down (Z1) and up (Z2). Accordingly, the Z1 direction is opposite the Z2 direction, reference to a lower or bottom side or a downwardly facing surface of a component may be referred to as a Z1 side or a Z1 surface, and reference to a top or upper side or upwardly facing surface of a component may be referred to as a Z2 side or a Z2 surface. Other orientations (e.g., tilted or angled orientations) can be made in accordance with the X1-X2 axis and Z1-Z2 axis.

The device 100 (also referred to herein as an LED assembly) can include a LED die 110, a ceramic converter 120, and a housing 130. The LED die 110 emits light (also referred to herein as pump light or pump radiation) in a Z2 direction. The ceramic converter 120 receives the pump light from the LED die 110 at a Z1 side and emits altered light from a Z2 side. As one of ordinary skill in the art would understand, light emitted from the Z2 side may include some light that is converted by phosphor particles in the ceramic converter 120 and some light that passes through the ceramic converter 120 unconverted. A combination of the converted and converted light that is emitted via the light-emitting surface of the ceramic converter 120 is what is referred to as the altered light. The housing 130 can be an over mold side coating for the device 100 that protects the LED die 110 and the ceramic converter 120 from external dust and other forces. The ceramic converter 120 can receive a dichroic filter (DCF) 140 at a Z2 side, which can be tuned to reflect back a pump radiation (e.g., emitted light from InGaN/GaN multi-quantum wells). More particularly, in the illustrated example, the DCF filter 140 is disposed on a surface 141 of the converter 120. The surface 141 may also be referred to herein as the light-emitting surface of the ceramic converter 120.

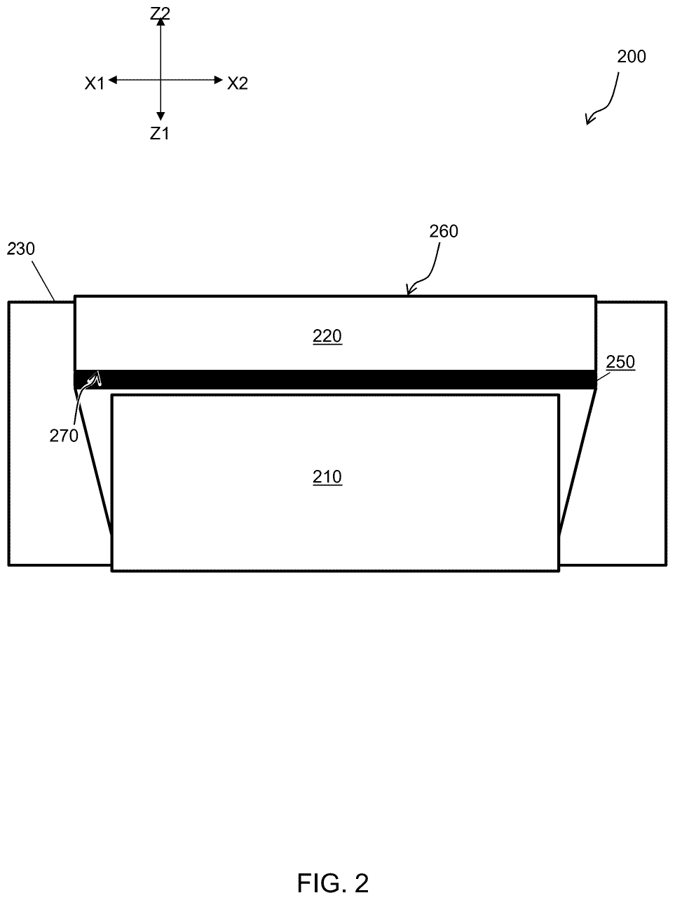

FIG. 2 shows a cross section of a device 200 according to one or more embodiments. The device 200 of FIG. 2 is shown as a cross section oriented according to an X1-X2 axis and a Z1-Z2 axis, as described herein. The device 200 can be considered an emitter chip scale packaging CSP architecture equipped with a LED die 210, a ceramic converter 220 (e.g., converter layer), a housing 230, and a filter 250 (a.k.a., a second filter, a light receiving filter, and an opposite side filter).

The ceramic converter 220 includes a LES 260 (e.g., a Z2 side) and an opposite side 270 of the LES (e.g., a Z1 side). Note that while a CSP is illustrated, other architectures are contemplated by the device 200 (e.g., thin-film flip-chip (TFFC) and vertically injected thin-film (VTF) architectures).

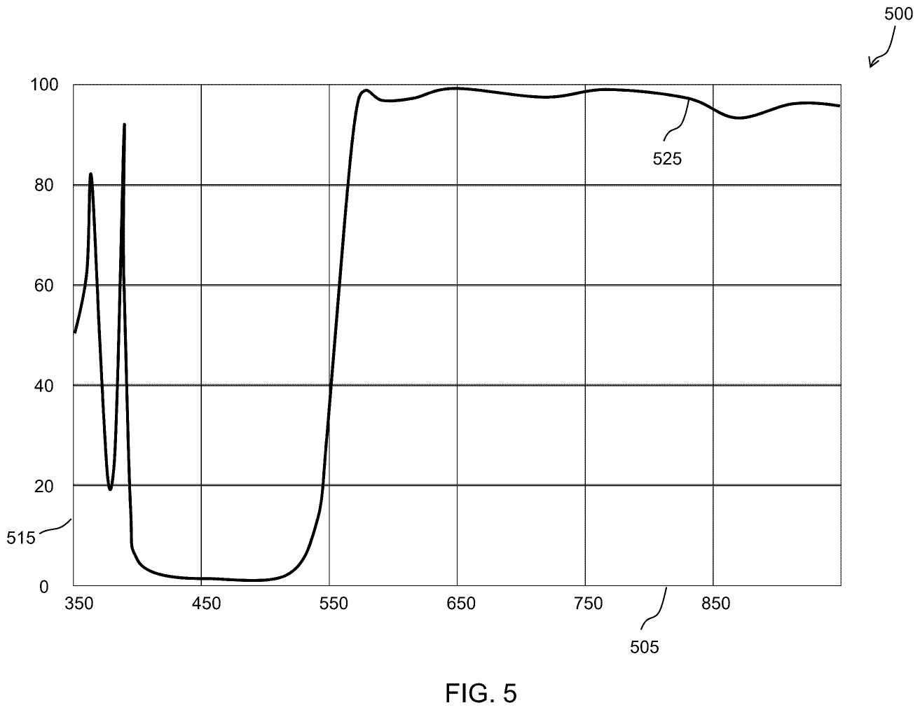

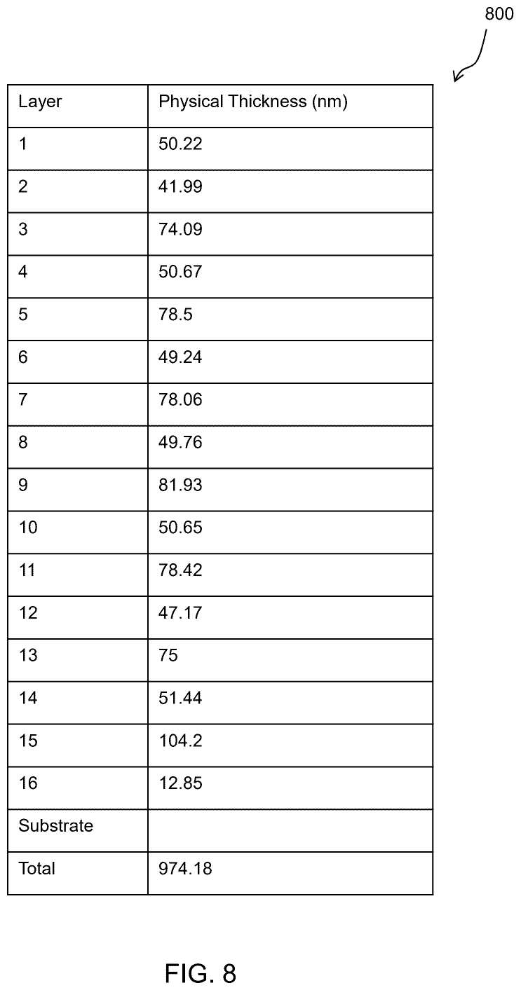

According to one or more embodiments, the filter 250 can include a combination of 17 layers or less. Examples of the filter 250 can include, but are not limited to, an interferometric photonic bandgap filter, an interferometric layer stack, and a DCF. The filter 250 can include one or more radiation characteristics that can be configured along quantitative ranges. These one or more radiation characteristics can include bandwidth of high transmission, band position within a spectral range, cut-off shapes (e.g. slope), and amplitudes. Further, the one or more radiation characteristics are described an shown with respect to FIGS. 5 and 8.

The LED die 210 emits light in a Z2 direction. Accordingly, the LED die 210 provides a pump radiation through the filter 250 and towards the converter 220 (e.g., the light in the Z2 direction). The ceramic converter 220 receives the light from a Z1 direction that has passed through the filter 250 from the LED die 210 at the opposite side 270. The ceramic converter 220 emits altered light, as defined above, via the LES 260. The housing 230 can be an over mold side coating for the device 200 that protects other components of the device 200 from external dust and other forces. According to one or more embodiments, the LED die 210 can include any LED die that emits red (e.g., approximately 620 nanometers to 750 nanometers) and/or infrared (e.g., approximately 750 nanometers to 1000 nanometers) pump light, as well as near-infrared pump light and other wavelength ranges. According to one or more embodiments, the LED die 210 can be a blue light LED die that emits blue pump light in a Z2 direction, and the ceramic converter 220 can be a ceramic pc-amber converter that receives the blue pump light through the filter 250 and emits light that appears to have an amber color.

In comparison to the device 100 illustrated in FIG. 1, the device 200 illustrated in FIG. 2 does not have a DCF filter 140 disposed on the LES 260 of the ceramic converter 220 (at the surface 141. Rather, the device 200 integrates the filter 250 at the opposite side 270 of the ceramic converter 220. More particularly, the filter 250 can be deposited on the opposite side 270 of the ceramic converter 220 (e.g., on the Z1 surface). Thus, the device 200 may provide an improvement in flux relative to the device 100 of FIG. 1.

According to one or more embodiments, the filter 250 is configured to influence a radiation profile of the pump light received from the LED 210. In this regard, the filter 250 can influence the radiation profile by manipulating radiation and/or variable transmission characteristics to increase a coupling efficiency of the pump radiation into the converter layer 220. The coupling efficiency of the filter 250 may refer to the transmission ability of the filter 250 to provide light from the LED 210. For example, the filter 250 can influence the radiation profile by controlling radiation characteristics, by controlling variable transmission characteristics over different regions of a light spectrum, by controlling variable transmission characteristics over different angular regions of emission, or by controlling one or more of radiation characteristics and variable transmission characteristics of the device 200.

For instance, the filter 250 can influence the radiation profile of the pump radiation to allow all blue light to enter the ceramic converter 220 at an increased transmission percentage (e.g., at an improved coupling efficiency).

According to one or more embodiments, the device 200 includes one or more anti-reflective coatings. The anti-reflective coating can be deposited on the filter 250 (e.g., on a Z1 side, on a Z2 side, or on both the Z1 and Z2 sides of the filter 250), the ceramic converter 220, or the filter 250 and the ceramic converter 220. Including an anti-reflective coating one or more sides of the filter 250 may provide for an LED light output that has an improved flux gain, a uniform emission profile, and/or an improved shade intensity.

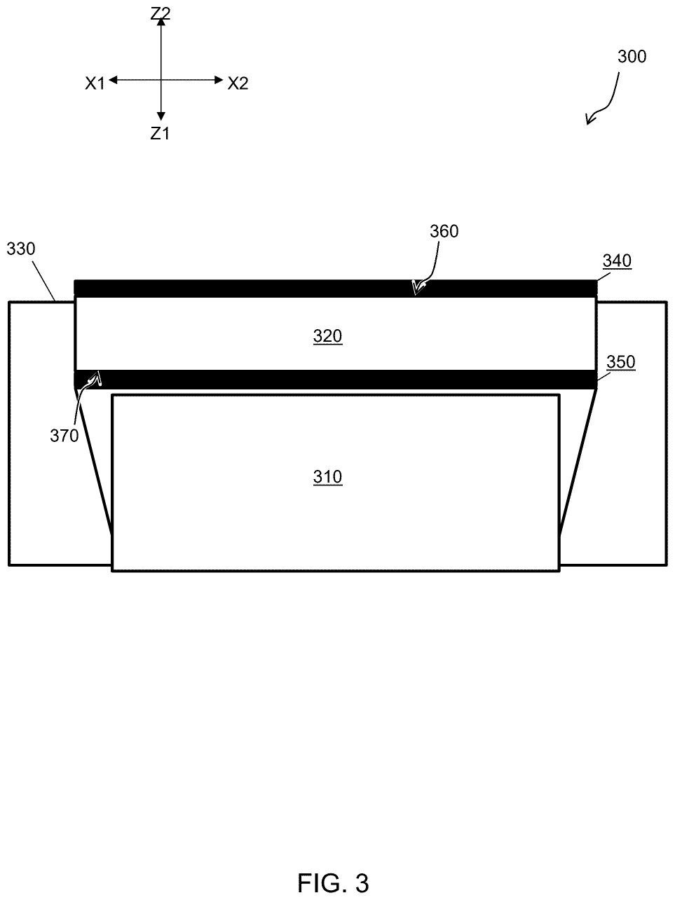

FIG. 3 shows a cross section of a device 300 according to one or more embodiments. The device 300 of FIG. 3 is shown as a cross section oriented according to an X1-X2 axis and a Z1-Z2 axis, as described herein. The device 300 can be considered an emitter chip scale packaging CSP architecture equipped with an LED die 310, a ceramic converter 320 (e.g., converter layer), a housing 330, a filter 340 (also referred to herein as a first filter, a light emitting filter, or an LES side filter), and a filter 350 (also referred to herein as a second filter, a light receiving filter, or an opposite side filter).

The ceramic converter 320 includes an LES 360 (e.g., a Z2 side) and an opposite side 370 of the LES (e.g., a Z1 side). While the device illustrated in FIG. 3 is a CSP LED device, other architectures are contemplated by the device 300, such as thin-film flip-chip (TFFC) and vertically injected thin-film (VTF) architectures.

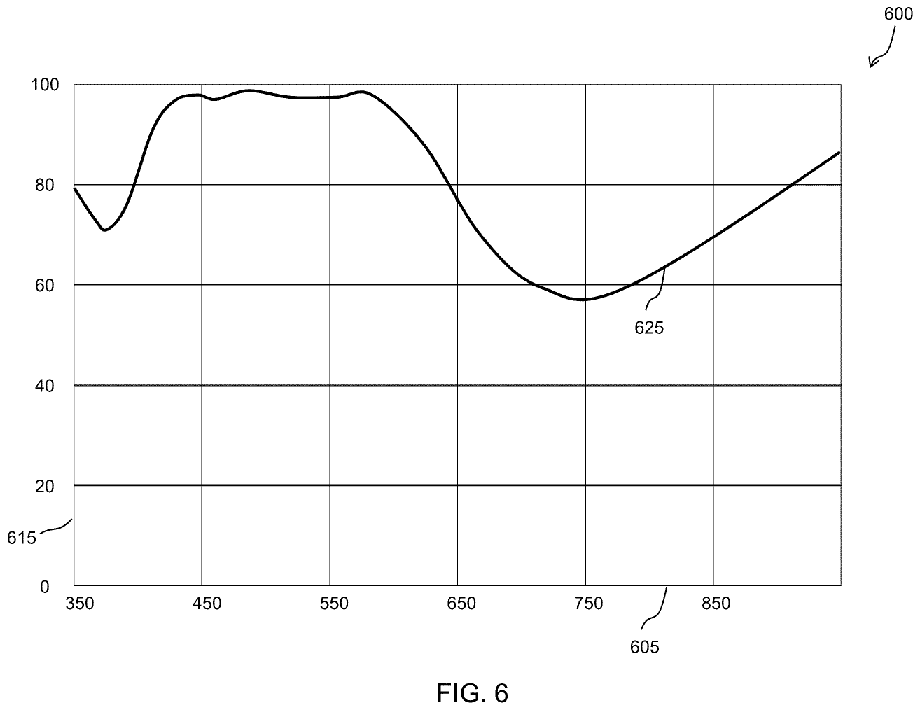

According to one or more embodiments, each filter 340 and 350 can include a combination of 17 layers or less. Examples of the filters 340 and 350 can include, but are not limited to, an interferometric photonic bandgap filter, an interferometric layer stack, and a DCF. The filters 340 and 350 can include one or more radiation characteristics that can be configured along quantitative ranges as described herein. Further, the one or more radiation characteristics are shown in, and described with respect to, FIGS. 6-7 and 9-10.

In the illustrated example, the LED die 310 emits light in a Z2 direction. Accordingly, the LED die 310 provides a pump radiation into the filter 350 and towards the converter 320. The ceramic converter 320 receives the pump light from the LED die 310 at the opposite side 370 from a Z1 direction (e.g., the converter layer including a light emitting surface and an opposite side of the LES). The ceramic converter 320 emits altered light, as defined herein, from the LES 360 through the filter 340. The housing 330 can be an over mold side coating for the device 300 that protects other components of the device 300 from external dust and other forces. According to one or more embodiments, the LED die 310 can be any LED die that emits red, infrared, and/or near-infrared pump light, by way of specific examples, but could be an LED die that emits light in any wavelength range so long as an appropriate ceramic converter 320 is selected. According to one or more embodiments, the LED die 310 can be a blue light LED die that emits blue pump light in a Z2 direction, and the ceramic converter 320 can be a ceramic pc-amber converter that receives the blue light and emits amber light.

As compared to the device 100 illustrated in FIGS. 1 and 2, the device 300 illustrated in FIG. 3 integrates the filters 340 and 350 on both surfaces 360 and 370 of the ceramic converter 320 (rather than disposing a single filter 140 on just the LES 360 or just the opposite surface 370). More particularly, the filter 340 can be deposited on the LES 360 of the ceramic converter 320, and the filter 350 can be deposited on the opposite surface 370 of the ceramic converter 320. Accordingly, the device 300 provides a flux improvement with respect to both the devices 100 and 200 of FIGS. 1 and 2, respectively.

According to one or more embodiments, one or both of the filters 340 and 350 are configured to influence a radiation profile of the light received from the LED 310 (e.g., a pump radiation). In this regard, the one or both of the filters 340 and 350 can influence the radiation profile by manipulating radiation and/or variable transmission characteristics to increase a coupling efficiency of the pump radiation into the converter layer 320. The coupling efficiency of the one or both of the filters 340 and 350 may be the transmission ability of the one or both of the filters 340 and 350 to provide pump light from the LED die 310. For example, one or both of the filters 340 and 350 can influence the radiation profile by a color control (e.g., control the intensity or candela produced by the LED die 310), by a flux control (e.g., control the visible/perceived light or brightness or lumens produced by the LED die 310), or by a flux and color control of the device 300. For another example, the one or both of the filters 340 and 350 can influence the radiation profile by controlling radiation characteristics, by controlling variable transmission characteristics over different regions of a light spectrum, by controlling variable transmission characteristics over different angular regions of emission, or by controlling one or more of radiation characteristics and variable transmission characteristics of the device 300.

For instance, the filter 350 can influence the radiation profile of the pump radiation to allow all or portions of the pump light to enter the ceramic converter 320 at an increased transmission percentage, and the filter 340 can reflect all or portions of the blue light back into the converter 320.

According to one or more embodiments, the device 300 includes one or more anti-reflective coatings. The anti-reflective coating can be deposited on one or both of the filters 340 and 350 (e.g., on a Z1 side, on a Z2 side, or on both the Z1 and Z2 sides of the filters 340 and 350), the ceramic converter 320, or the one or both of the filters 340 and 350 and the ceramic converter 320. The device 300 provides an output light that has an improved flux gain, a uniform emission profile, and/or an improved shade intensity.

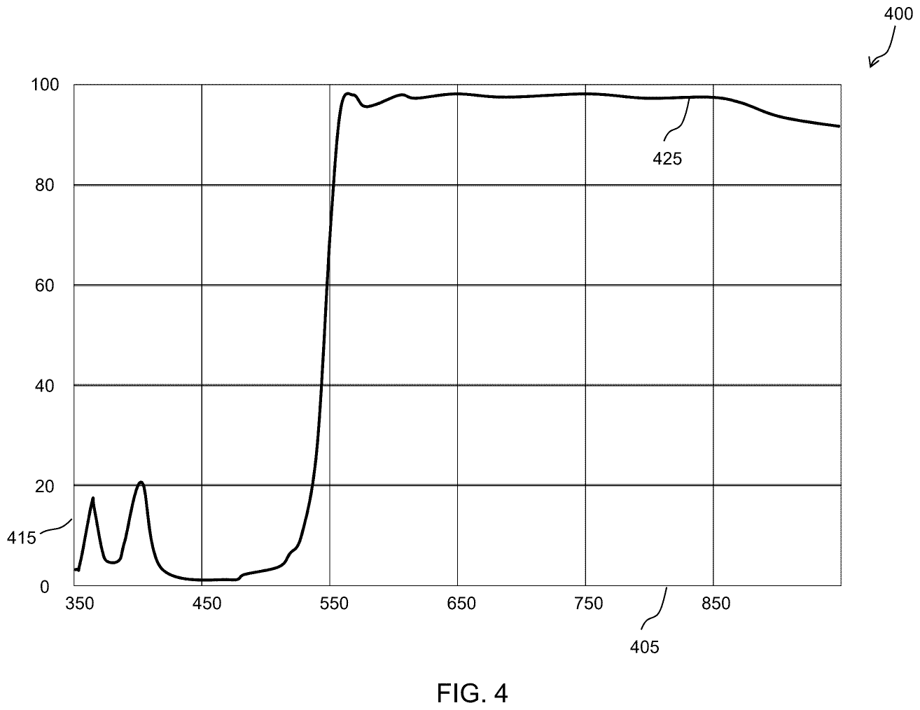

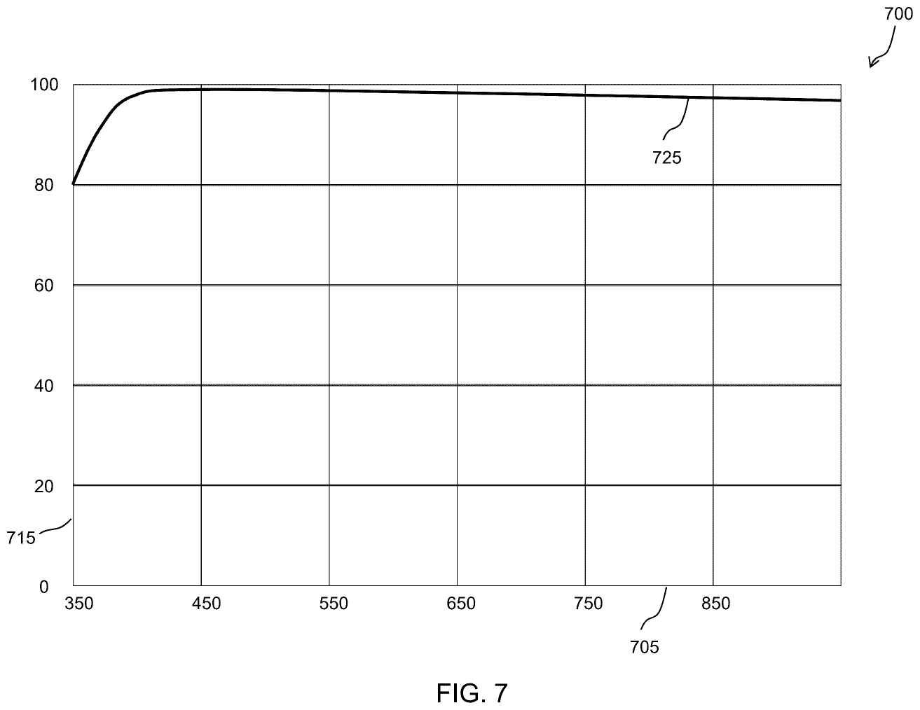

FIG. 4 depicts a graph 400 according to one or more embodiments. FIG. 5 depicts a graph 500 according to one or more embodiments. FIG. 6 depicts a graph 600 according to one or more embodiments. FIG. 7 depicts a graph 700 according to one or more embodiments. The graphs 400, 500, 600, and 700 respectively include x-axes 405, 505, 605, and 705 depicting wavelength in nanometers (nm) and y-axes 415, 515, 615, and 715 depicting transmittance in percentage (%).

The graph 400 plots transmission characteristics of the filter 140 of FIG. 1, with the graph 400 including a plot 425. The graph 500 plots transmission characteristics of example interferometric filter for the LES (e.g., the filter 340 of FIG. 3), with the graph 500 including a plot 525. The example interferometric filter respective to graph 400 includes a POR structure. The example interferometric filter respective to graph 500 includes a DCF structure. The plots 425 and 525 demonstrate a light transmission for the POR and DCF structures at a particular wavelength when the angle of incident is zero (0) degrees. FIG. 8 depicts a table 800 according to one or more embodiments. The table 800 shows a layer structure corresponding to example interferometric filter respective to graph 500. The layer structure corresponding to example interferometric filter respective to graph 500 can include sixteen (16) layers or less that can combine to a total thickness of 0.98 μm or less.

Generally, the POR structure can have twenty-one or more layers for thickness of at least 1.17 microns (μm). An improvement over the POR structure of the graph 400 by the DCF structure of the graph 500 is a reduction of layers and overall thickness (e.g., table 800 shows a total thickness of 0.97 μm based on a combination of 16 layers), which leads to reduced absorption by the DCF structure. In the illustrated example, the reflectance has increased for wavelengths approximate to 550 nm for the plot 525. By way of example, as blue light typically has wavelengths of 450 nm to 495 nm, the graph 500 shows an improvement on the reflection of the blue light (e.g., from 380 nm to 550 nm) back into the converter 320. For instance, the plot 525 demonstrates a cut-off shape (e.g., slope) at approximately 550 nm.

The graphs 600 and 700 plot transmission characteristics of interferometric filters for the opposite surface of the converter layer (e.g., the filter 250 of FIG. and the filter 350 of FIG. 3), with the graph 600 including a plot 625 and the graph 700 including a plot 725. The example interferometric filters respective to graphs 600 and 700 include DCF structures.

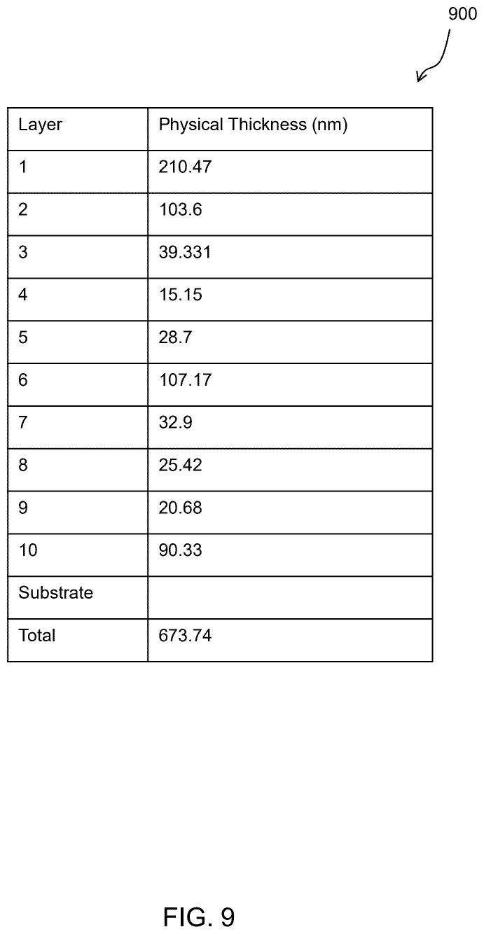

FIG. 9 depicts a table 900 according to one or more embodiments. The table 900 shows a layer structure corresponding to the example interferometric filter respective to graph 600. In the example illustrated in FIG. 9, the layer structure that produced the transmission characteristics plotted in FIG. 6 is an interferometric filter that includes ten (10) layers or less that can combine to a total thickness of 0.68 μm or less.

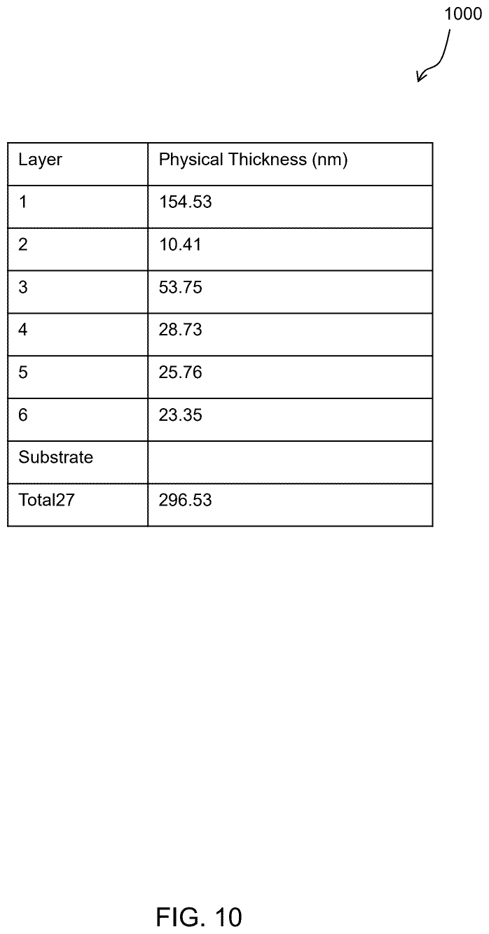

FIG. 10 depicts a table 1000 according to one or more embodiments. The table 1000 shows a layer structure corresponding to the example interferometric filter respective to graph 700. In the example illustrated in FIG. 10, the layer structure that produced the transmission characteristics plotted in FIG. 7 is an interferometric filter that includes six (6) layers or less that can combine to a total thickness of 0.30 μm or less. The plots 625 and 725 demonstrate a light transmission for the layer structures at a particular wavelength when the angle of incidence is zero (0) degrees. For instance, the plot 625 demonstrates a bandwidth (e.g., from 400 nm to 600 nm) of high transmission (e.g., greater than 95%). Note that the graphs 400, 500, 600, and 700 show other characteristics including band position within a spectral range and amplitudes.

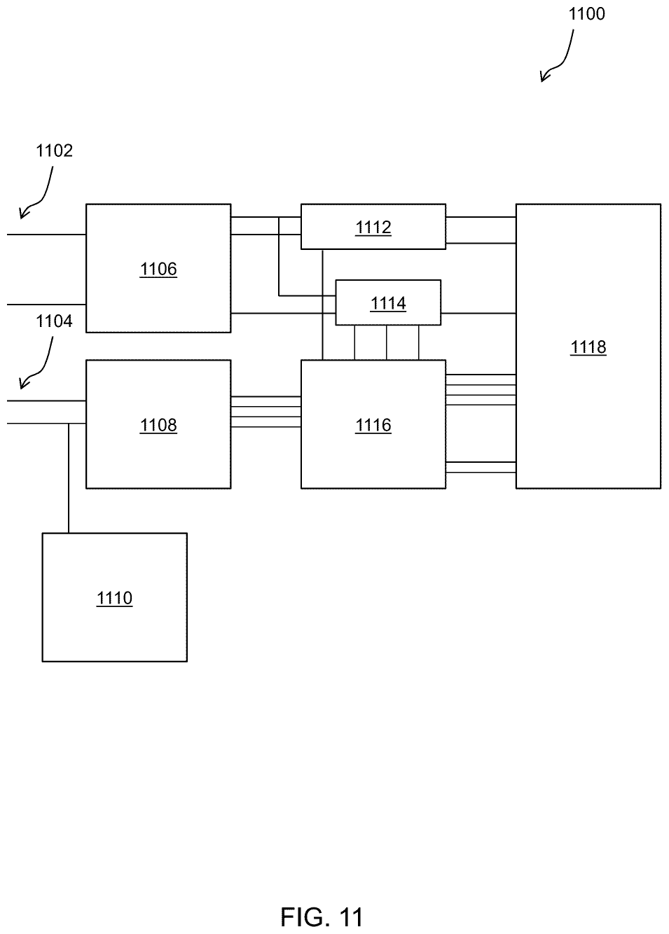

FIG. 11 is a diagram of an example vehicle headlamp system 1100 that may incorporate one or more of the embodiments and examples described herein. The example vehicle headlamp system 1100 illustrated in FIG. 11 includes power lines 1102, a data bus 1104, an input filter and protection module 1106, a bus transceiver 1108, a sensor module 1110, an LED direct current to direct current (DC/DC) module 1112, a logic low-dropout (LDO) module 1114, a micro-controller 1116, and an active head lamp 1118.

The power lines 1102 may have inputs that receive power from a vehicle, and the data bus 1104 may have inputs/outputs over which data may be exchanged between the vehicle and the vehicle headlamp system 1100. For example, the vehicle headlamp system 1100 may receive instructions from other locations in the vehicle, such as instructions to turn on turn signaling or turn on headlamps, and may send feedback to other locations in the vehicle if desired. The sensor module 1110 may be communicatively coupled to the data bus 1104 and may provide additional data to the vehicle headlamp system 1100 or other locations in the vehicle related to, for example, environmental conditions (e.g., time of day, rain, fog, or ambient light levels), vehicle state (e.g., parked, in-motion, speed of motion, or direction of motion), and presence/position of other objects (e.g., vehicles or pedestrians). A headlamp controller that is separate from any vehicle controller communicatively coupled to the vehicle data bus may also be included in the vehicle headlamp system 1100. In FIG. 11, the headlamp controller may be a micro-controller, such as micro-controller (pc) 1116. The micro-controller 1116 may be communicatively coupled to the data bus 1104.

The input filter and protection module 1106 may be electrically coupled to the power lines 1102 and may, for example, support various filters to reduce conducted emissions and provide power immunity. Additionally, the input filter and protection module 1106 may provide electrostatic discharge (ESD) protection, load-dump protection, alternator field decay protection, and/or reverse polarity protection.

The LED DC/DC module 1112 may be coupled between the input filter and protection module 116 and the active headlamp 1118 to receive filtered power and provide a drive current to power LEDs in the LED array in the active headlamp 1118. The LED DC/DC module 1112 may have an input voltage between 11 and 18 volts with a nominal voltage of approximately 13.2 volts and an output voltage that may be slightly higher (e.g., 0.3 volts) than a maximum voltage for the LED array (e.g., as determined by factor or local calibration and operating condition adjustments due to load, temperature or other factors).

The logic LDO module 1114 may be coupled to the input filter and protection module 1106 to receive the filtered power. The logic LDO module 1114 may also be coupled to the micro-controller 1116 and the active headlamp 1118 to provide power to the micro-controller 1116 and/or electronics in the active headlamp 1118, such as CMOS logic.

The bus transceiver 1108 may have, for example, a universal asynchronous receiver transmitter (UART) or serial peripheral interface (SPI) interface and may be coupled to the micro-controller 1116. The micro-controller 1116 may translate vehicle input based on, or including, data from the sensor module 1110. The translated vehicle input may include a video signal that is transferrable to an image buffer in the active headlamp 1118. In addition, the micro-controller 1116 may load default image frames and test for open/short pixels during startup. In embodiments, an SPI interface may load an image buffer in CMOS. Image frames may be full frame, differential or partial frames. Other features of micro-controller 1116 may include control interface monitoring of CMOS status, including die temperature, as well as logic LDO output. In embodiments, LED DC/DC output may be dynamically controlled to minimize headroom. In addition to providing image frame data, other headlamp functions, such as complementary use in conjunction with side marker or turn signal lights, and/or activation of daytime running lights, may also be controlled.

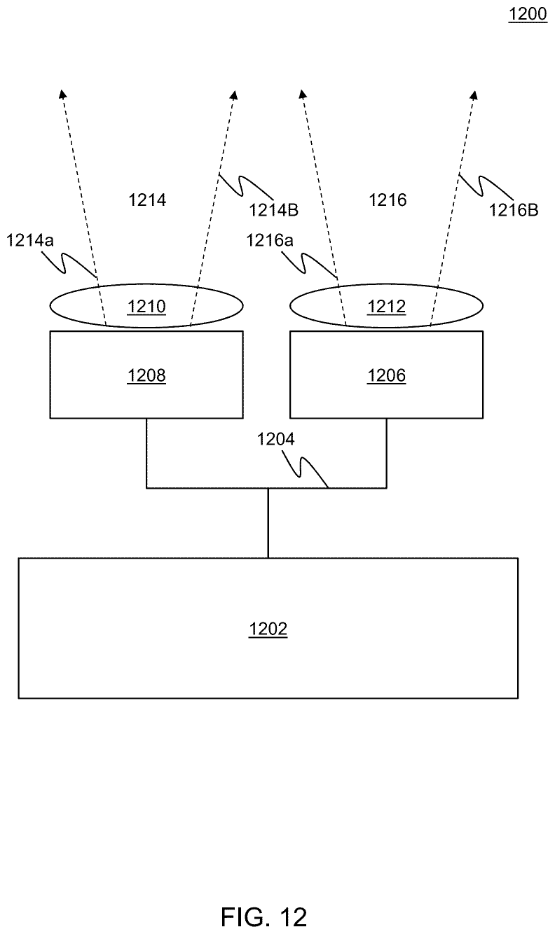

FIG. 12 is a diagram of another example vehicle headlamp system 1200. The example vehicle headlamp system 1200 illustrated in FIG. 12 includes an application platform 1202, two LED lighting systems 1206 and 1208, and secondary optics 1210 and 1212.

The LED lighting system 1208 may emit light beams 1214 (shown between arrows 1214a and 1214b in FIG. 12). The LED lighting system 1206 may emit light beams 1216 (shown between arrows 1216a and 1216b in FIG. 12). In the embodiment shown in FIG. 12, a secondary optic 1210 is adjacent the LED lighting system 1208, and the light emitted from the LED lighting system 1208 passes through the secondary optic 1210. Similarly, a secondary optic 1212 is adjacent the LED lighting system 1206, and the light emitted from the LED lighting system 1206 passes through the secondary optic 1212. In alternative embodiments, no secondary optics 1210/812 are provided in the vehicle headlamp system.

Where included, the secondary optics 1210/812 may be or include one or more light guides. The one or more light guides may be edge lit or may have an interior opening that defines an interior edge of the light guide. LED lighting systems 1208 and 1206 may be inserted in the interior openings of the one or more light guides such that they inject light into the interior edge (interior opening light guide) or exterior edge (edge lit light guide) of the one or more light guides. In embodiments, the one or more light guides may shape the light emitted by the LED lighting systems 1208 and 1206 in a desired manner, such as, for example, with a gradient, a chamfered distribution, a narrow distribution, a wide distribution, or an angular distribution.

The application platform 1202 may provide power and/or data to the LED lighting systems 1206 and/or 1208 via lines 1204, which may include one or more or a portion of the power lines 1102 and the data bus 1104 of FIG. 11. One or more sensors (which may be the sensors in the vehicle headlamp system 1200 or other additional sensors) may be internal or external to the housing of the application platform 1202. Alternatively, or in addition, as shown in the example vehicle headlamp system 1100 of FIG. 11, each LED lighting system 1208 and 1206 may include its own sensor module, connectivity and control module, power module, and/or LED array.

In embodiments, the vehicle headlamp system 1200 may represent an automobile with steerable light beams where LEDs may be selectively activated to provide steerable light. For example, an array of LEDs or emitters may be used to define or project a shape or pattern or illuminate only selected sections of a roadway. In an example embodiment, infrared cameras or detector pixels within LED lighting systems 1206 and 1208 may be sensors (e.g., similar to sensors in the sensor module 1110 of FIG. 11) that identify portions of a scene (e.g., roadway or pedestrian crossing) that require illumination.

As would be apparent to one skilled in the relevant art, based on the description herein, embodiments of the present invention can be designed in software using a hardware description language (HDL) such as, for example, Verilog or VHDL. The HDL-design can model the behavior of an electronic system, where the design can be synthesized and ultimately fabricated into a hardware device. In addition, the HDL-design can be stored in a computer product and loaded into a computer system prior to hardware manufacture.

Having described the embodiments in detail, those skilled in the art will appreciate that, given the present description, modifications may be made to the embodiments described herein without departing from the spirit of the inv concept. Therefore, it is not intended that the scope of the invention be limited to the specific embodiments illustrated and described.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

What is claimed is:

1. A device comprising:
a converter layer comprising a light emitting surface and an opposite side of the light emitting surface; and
a filter deposited on the opposite side and configured to influence a radiation profile to increase a coupling efficiency of a pump radiation into the converter layer.

2. The device of claim 1, wherein the filter is configured to influence the radiation profile by controlling one or more radiation characteristics of light received from a light emitting diode.

3. The device of claim 2, wherein the one or more radiation characteristics comprises a bandwidth from 400 nm to 600 nm and a transmission greater than 95%.

4. The device of claim 1, wherein the filter comprises an interferometric photonic bandgap filter.

5. The device of claim 1, wherein the filter comprises an interferometric layer stack.

6. The device of claim 1, wherein the filter comprises a dichroic filter.

7. The device of claim 1, wherein the device further comprises a second filter deposited on the light emitting surface.

8. The device of claim 7, wherein the second filter comprises an interferometric photonic bandgap filter.

9. The device of claim 7, wherein the second filter is configured to reflect one or more portions of light back into the converter.

10. The device of claim 9, wherein the one or more portions of light comprise light having wavelengths in a range between 380 nanometers (nm) to 550 nanometers (nm).

11. The device of claim 1, wherein the filter is configured to influence the radiation profile by controlling variable transmission characteristics over different regions of a visible spectrum.

12. The device of claim 1, wherein the filter is configured to influence the radiation profile by controlling variable transmission characteristics over different angular regions of emission.

13. The device of claim 1, wherein the converter layer comprises a phosphor converted amber converter.

14. The device of claim 1, wherein the device comprises a light emitting diode (LED) die providing the pump radiation into the filter and towards the converter layer.

15. The device of claim 1, wherein the device comprises an anti-reflective coating on the filter.

16. The device of claim 1, wherein the device comprises a light emitting diode emitting blue light, red light, or infrared light.

17. An apparatus comprising:
a light emitting diode (LED) die configured to emit a pump light when powered on;
a converter layer comprising a light emitting surface (LED) and an opposite side surface opposite the LED, the converter layer disposed over the LED die with the opposite side surface adjacent the LED die;
a first filter between the opposite side surface of the converter layer and the LED die, the first filter being configured to influence a radiation profile of the pump light; and
a second filter on the LES of the converter layer and configured to reflect one or more portions of the pump light into the converter.

18. The apparatus of claim 17, wherein the first filter influences a radiation profile of light emitted out of the apparatus by transmitting 95% of the light within a bandwidth from 400 nm to 600 nm.

19. The apparatus of claim 17, wherein the first filter comprises an interferometric photonic bandgap filter, an interferometric layer stack, or a dichroic filter, and the second filter comprises an interferometric photonic bandgap filter.

20. The apparatus of claim 17, wherein the one or more portions of the pump light comprise light having wavelengths in a range between 380 nm to 550 nm.
